(19) United States
(12) Patent Application Publication
(10) Pub. No.: US 2003/0008516 A1
(43) Pub. Date: Jan. 9, 2003

(54) Method of reinforcing a low dielectric constant material layer against damage caused by a photoresist stripper

(76) Inventors: Ting-Chang Chang, Hsin-Chu City (TW); Po-Tsun Liu, Hsin-Chu City (TW); Yi-Shien Mor, Taipei City (TW)

Correspondence Address: NAIPO (NORTH AMERICA INTERNATIONAL PATENT OFFICE), P.O. BOX 506, MERRIFIELD, VA, 22116, US

(21) Appl. No.: 09/681,985

(22) Filed: Jul. 3, 2001

(51) Int. Cl. H01L 21/302; H01L 21/461

(52) U.S. Cl. 438/704

(57) ABSTRACT

A low dielectric constant (low k) material layer is positioned on a semiconductor wafer. A first hydrogen-containing plasma treatment is performed to reinforce a surface of the low k material layer against corrosion caused by a photoresist stripper. A photoresist layer, having an opening in the photoresist layer to expose portions of the low k material layer, is then coated on the low k material layer. By dry etching the low k material layer through the opening, a pattern in the photoresist layer is transferred to the low k material layer. An ashing process with an oxygen plasma supply is then performed to ash the photoresist layer. Finally, the semiconductor wafer is dipped in a wet stripper to completely remove the photoresist layer.

### BACKGROUND OF INVENTION

1.Field of the Invention

The present invention relates to a method of reinforcing a low dielectric constant (low k) material layer against damage caused by a photoresist stripper, and more specifically, to a method of reinforcing a low k material layer against damage caused by a photoresist stripper by performing a hydrogen-containing plasma treatment on the low k material layer.

2. Description of the Prior Art

With the decreasing size of semiconductor devices and an increase in integrated circuit (IC) density, RC time delay effects, produced between the metal wires, seriously affect IC operation and performance and reduces IC operating speed. RC time delay effects are more obvious especially when the line width is reduced to 0.25 μm, even 0.13 μm in a semiconductor process.

RC time delay effects produced between metal wires is a product of the electrical resistance (R) of the metal wires and the parasitic capacitance (C) of a dielectric layer between the metal wires. Normally RC time delay effects can be reduced byeither using conductive materials with a lower resistance such as a metal wire, or reducing the parasitic capacitance of the dielectric layer between metal wires. In the approach of using a metal wire with a lower resistance, copper interconnection technology replaces the traditional Al:Cu (0.5%) alloy fabrication process and is a necessary tendency in multilevel metallization processes. Due to copper having a low resistance (1.67 μΩ-cm) and higher current density load without electro-migration in the Al/Cu alloy, the parasitic capacitance between metal wires and connection levels of metal wires is reduced. However, reducing RC time delay produced between metal wires by only copper interconnection technology is not enough. Also, some fabrication problems of copper interconnection technology need to be solved. Therefore, it is more and more important to reduce RC time delay by the approach of reducing the parasitic capacitance of the dielectric layer between metal wires.

Additionally, the parasitic capacitance of a dielectric layer is related to the dielectric constant of the dielectric layer. As the dielectric constant of the dielectric layer is lower, the parasitic capacitance of the dielectric layer is lower. Traditionally silicon dioxide, having a dielectric constant of 3.9, cannot meet the requirement of 0.13 μm in semiconductor processes, so some new low k materials, such as polyimide (PI), FLARE™, FPI, PAE-2, PAE-3 or LOSP are thereby consecutively proposed. However, these low k materials are composed of carbon, hydrogen and oxygen and have significantly different properties to those of traditional silicon dioxide used in etching or adhering with other materials. Most of these low k materials have some disadvantages such as poor adhesion and poor thermal stability, so they cannot properly integrate into current IC fabrication processes.

Therefore, another kind of low k dielectric layer, such as hydrogen silsesquioxane (HSQ), methyl silsesquioxane (MSQ) and HOSP, respectively having dielectric constants of 2.8, 2.7 and 2.5 respectively, using the silicon dioxide as a base and adding some carbon and hydrogen elements inside is needed. These silicon based low k materials have potential in the future since properties of these materials resemble traditional silicon dioxide and can be easily integrated into the current IC fabrication process.

Please refer to FIG. 1 to FIG. 3 of schematic views of removing a photoresist layer according the prior art. As shown in FIG. 1, a semiconductor wafer 10 comprises a silicon substrate 12 and a low k material layer 14, composed of SiO₂-based materials such as hydrogen silsesquioxane (HSQ), methyl silsesquioxane (MSQ) and HOSP, formed on the silicon substrate 12 by performing a chemical vapor deposition (CVD) process or a spin-on process.

As shown in FIG. 2, a photoresist layer 16 is coated on the low k material layer 14 and an opening 18 is formed in the photoresist layer 16 to expose portions of the low k material layer 14 thereafter. By performing a dry etching process to etch the low k material layer 14 through the opening 18, a pattern in the photoresist layer 16 is transferredto the low k material layer 14.

As shown in FIG. 3, a stripping process, comprising an ashing process and a dipping process, is performed. By performing the ashing process with an oxygen plasma supply, gaseous carbon dioxide and water vapor are formed by a reaction between the oxygen plasma and carbon and hydrogen atoms in the photoresist layer 16. The photoresist layer 16 is thus stripped. Finally, the semiconductor wafer 10 is dipped in the photoresist stripper to completely remove the photoresist layer 16.

However, when patterning a dielectric layer composed of SiO₂-based low k materials, such as HSQ, MSQ or HOSP, the dielectric layer suffers some damage during an etching or stripping process. Since a dry oxygen plasma ashing process and a wet stripper are frequently employed in the stripping process to remove a photoresist layer, bonds in a surface of the dielectric layer are easily broken by oxygen plasma bombardment and react with oxygen ions as well as with wet stripper to form Si—OH bonds. Since the Si—OH bonds absorb water moisture, having a dielectric constant of approximately 78, the dielectric constant and leakage current of the dielectric layer are consequently increased, and even a phenomenon of poison via occurs, thereby seriously affecting the reliability of products.

### SUMMARY OF INVENTION

It is therefore a primary object of the present invention to provide a method of reinforcing a low dielectric constant (low k) material layeragainst damage caused by a photoresist stripper so as to prevent an increase in either dielectric constant or current leakage of the low k material layer.

According to the claimed invention, a low k material layer is positioned on a semiconductor wafer. At the beginning of the method, a first hydrogen-containing plasma treatment is performed to reinforce a surface of the low k material layer against corrosion caused by a photoresist stripper. A photoresist layer is then formed on the low k material layer with an opening in the photoresist layer to expose portions of the low k material layer. By performing an ashing process with an oxygen plasma supply, the photoresist layer is ashed thereafter. A second hydrogen-containing plasma treatment is then performed to further reinforce the low k material layer against the corrosion of the photoresist stripper. Finally, the semiconductor wafer is dipped into the photoresist stripper to completely remove the photoresist layer.

It is an advantage of the present invention against the prior art that a hydrogen-containing plasma treatment is performed on the low k material layer to form a passivation layer on the low k material layer before performing the dry etching process. Reactions betweeneither the oxygen plasma or the wet stripper and the low k material layer during the stripping process are thus inhibited. Therefore, damage to the low k material layer caused by the photoresist stripperin subsequent stripping processesis prevented. In addition, the present invention efficiently preventsthe formation of Si—OH in the low k material layer. Consequently, an increase in either dielectric constant or current leakage of the low k material layer is prevented as well.

These and other objectives of the present invention will no doubt become obvious to those of ordinary skill in the art after reading the following detailed description of the preferred embodiment, which is illustrated in the multiple figures and drawings.

### BRIEF DESCRIPTION OF DRAWINGS

FIG. 1 to FIG. 3 are schematic views of removing a photoresist layer according the prior art.

FIG. 4 to FIG. 8 are schematic views of reinforcing a low dielectric constant (low k) material layer against damage caused by a photoresist stripper according to the present invention.

FIG. 9 is an infrared spectroscopy of a HSQ dielectric layer at different process times in the first hydrogen-containing plasma treatment according to the present invention.

FIG. 10 and FIG. 11 are charts showing a relationship between electrical field and current leakage density of the HSQ dielectric layer at different process time intervals during the hydrogen-containing plasma treatment according to the present invention.

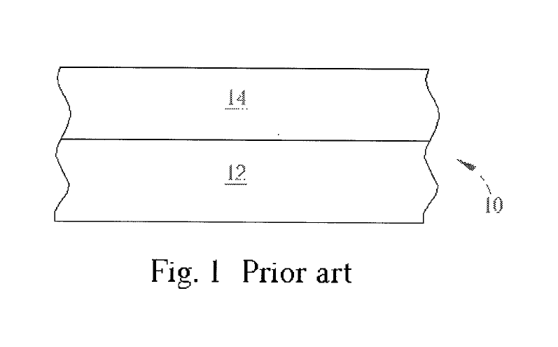

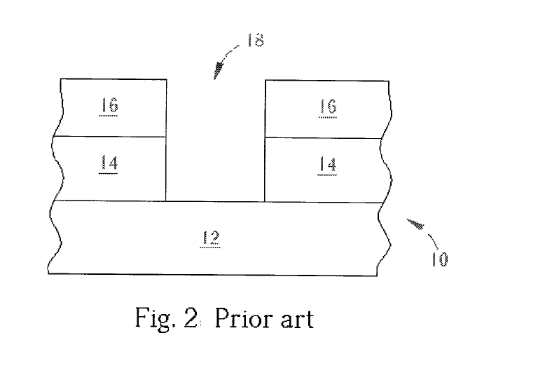

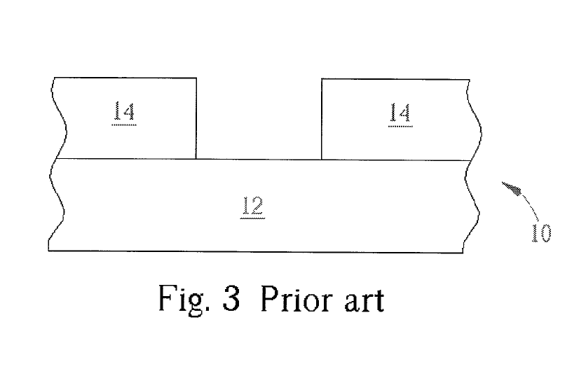

### DETAILED DESCRIPTION

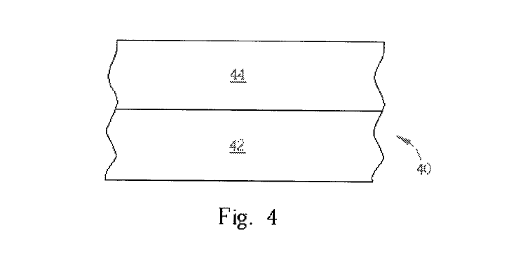

Please refer to FIG. 4 to FIG. 8 of schematic views of reinforcing a low dielectric constant (low k) material layer against damage caused by a photoresist stripper according to the present invention. As shown in FIG. 4, a semiconductor wafer 40 comprises a silicon substrate 42 and a low k material layer 44, composed of SiO₂-based materials such as hydrogen silsesquioxane (HSQ), methyl silsesquioxane (MSQ) and HOSP, respectively having dielectric constants of 2.8, 2.7 and 2.5, formed on the silicon substrate 42 by performing a chemical vapor deposition (CVD) process or a spin-on process.

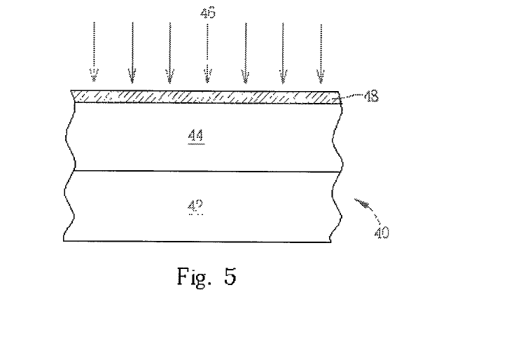

As shown in FIG. 5, a hydrogen-containing plasma treatment 46, with hydrogen plasma formed at a temperature ranging from 200 to 350° C. and in a pressure ranging from 200 to 350 mTorrusing hydrogen, having a flow rate ranging from 200 to 350 standard cubic centimeters per minute (sccm), with a radio frequency power (RF power) ranging from 90 to 150 Watts, is then performed on the low k material layer 44 for at least one minute. Since the low k material layer 44 comprises silicon and oxygen atoms, a surface of the low k material layer 44 reacts with hydrogen-containing plasma to form a passivation layer 48. The passivation layer 18 efficiently prevents moisture absorption in the low k material layer 44 and can be used as a barrier layer to inhibit copper diffusion.

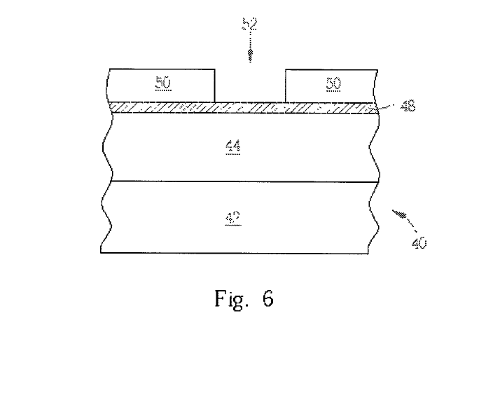

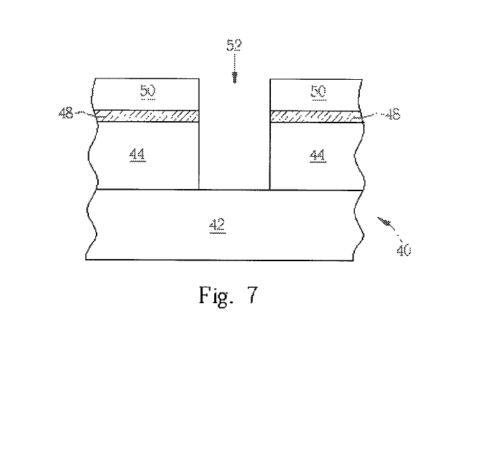

As shown in FIG. 6, a photoresist layer 50 is then coated on the low k material layer 44 and an opening 52 is formed in the photoresist layer 50 to expose portions of the low k material layer 44 thereafter. As shown in FIG. 7, a dry etching process is performed to etch the low k material layer 44 through the opening 52 to transfer a pattern in the photoresist layer 50 to the low k material layer 44.

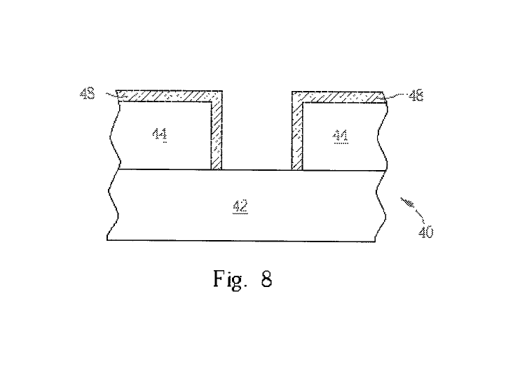

As shown in FIG. 8, a stripping process, comprising an ashing process, a second hydrogen-containing plasma treatment and a dipping process, is performed. By performing the ashing process with an oxygen plasma supply, gaseous carbon dioxide and water vapor are formed by a reaction between the oxygen plasma and carbon and hydrogen atoms in the photoresist layer 50. The photoresist layer 50 is thus stripped.

The second hydrogen-containing plasma treatment is then performed to further reinforce the low k material layer 44 against the corrosion of a photoresist stripper.

Finally, the semiconductor wafer 40 is dipped in the photoresist stripper, the photoresist stripper normally being ACT-935, to completely remove the photoresist layer 50.

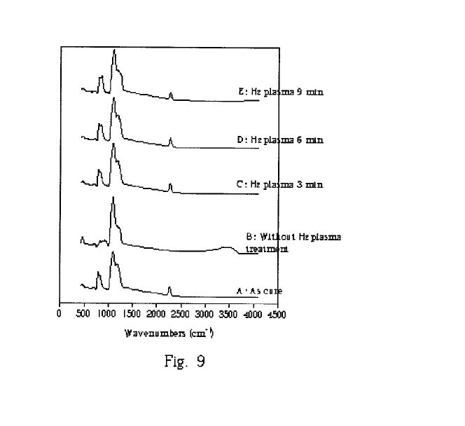

Due to the formation of the passivation layer 48 on the surface of the low k material layer 44, the low k material layer 44 is not damaged during the stripping process to form moisture absorbing Si—OH bonds. Therefore, the dielectric constant and current leakage of the low k material layer 44 do not increase so that deterioration of the dielectric characteristic of the low k material layer 44 is prevented. Please refer to FIG. 9 of an infrared spectroscopy of a HSQ dielectric layer at different process times in the first hydrogen-containing plasma treatment 46 according to the present invention. As shown in FIG. 9, curves A and B respectively represent infrared spectroscopy of the HSQ dielectric layer before and after the stripping process without performing the hydrogen-containing plasma treatment 46, andcurves C, D, and E, respectively represent infrared spectroscopy of the HSQ dielectric layer performing the hydrogen-containing plasma treatment 46 at 3, 6, and 9 minutes before the stripping process. Wherein, the absorption peak 1 and absorption peak 2 respectively represent the absorption of Si—H and Si—OH bonds that absorb infrared waves to 2200-2300 cm⁻¹ and 3000-3500 cm⁻¹, respectively.

Comparing curve A and curve B, following the HSQ dielectric layer performing stripping process, the peak 1 of the Si—H bond disappears and the Si—OH bonds appear in the HSQ dielectric layer, thus proving that the surface structure of the HSQ dielectric layer is damaged during the stripping process. But in curves C, D, and E, the peak 1 still exists and peak 2 does not appear. This shows that the hydrogen-containing plasma treatment 46 efficiently prevents the Si—H bond from being broken and preventsthe formation of Si—OH bonds during the stripping process. Besides, the absorption of peak 1 obviously decreases as a process time of the hydrogen-containing plasma treatment 46 increases. Therefore, less than 20 minutes of the hydrogen-containing plasma treatment 46 is suggested as the Si—H bonds in the HSQ dielectric layer become damaged due to a long process time.

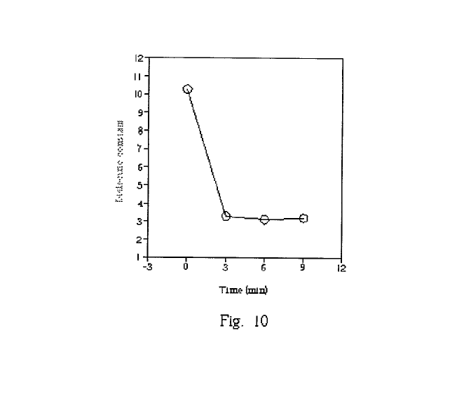

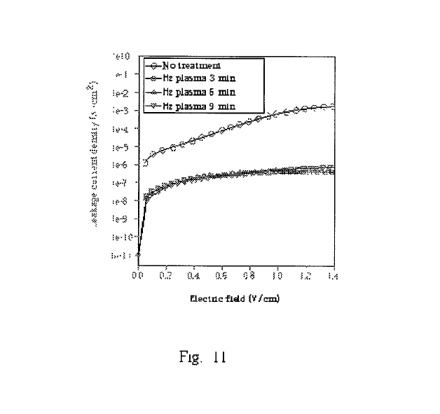

Please refer to FIG. 10 and FIG. 11 of charts showing a relationship between the dielectric constant of the HSQ dielectric layer at different process time intervals during the hydrogen-containing plasma treatment 46 according to the present invention. FIG. 10 is a relationship between electrical field and current leakage density of the HSQ dielectric layer at different process time intervals during the hydrogen-containing plasma treatment 46. As shown in FIG. 10, the dielectric constant of the HSQ dielectric layer during the hydrogen-containing plasma treatment 46 at times of 3, 6 and 9 minutes respectively is lower than the dielectric constant of the HSQ dielectric without performing thehydrogen-containing plasma treatment 46 (0 minutes). When performing the hydrogen-containing plasma treatment 46 for more than 3 minutes, the dielectric constant value remains constant, showing that an increase in the period of the hydrogen-containing plasma treatment 46 does not affect the dielectric constant. FIG. 11 also shows the same result, where square, upward-pointing triangle, downward-pointing triangle respectively represent the relationship of the electric field and the current leakage density in HSQ dielectric layer at 3, 6, and 9 minutes of the hydrogen-containing plasma treatment 46. Circle represents the relationship of the electric field and the current leakage density in the HSQ dielectric layer without performing the hydrogen-containing plasma treatment 46. As shown in FIG. 11, the current leakage of the HSQ dielectric layer undergoing the hydrogen-containing plasma treatment 46 (3, 6, 9 min) is significantly reduced by a factor or 100 or 1000 when compared to the dielectric layer that does not undergo the hydrogen-containing plasma treatment 46. After the hydrogen-containing plasma treatment 46 for 3 minutes, increasing the process time of the hydrogen plasma treatment does not significantly affect the current leakage, so 3 minutes is chosen as the process time for the hydrogen-containing plasma treatment 46 for the preferred embodiment of the present invention.

In comparison with the prior art, the hydrogen-containing plasma treatment 46 is performed on the low k material layer 44 to form the passivation layer 48 on the low k material layer 44 before performing the dry etching process so as to inhibit the oxygen plasma and the wet stripper reacts with the low k material layer 44 during the stripping process. Damage to the low k material layer 44 caused by the photoresist stripper is thus prevented. In addition, the present invention efficiently preventsthe formation of Si—OH in the low k material layer 44. Consequently, an increase in either the dielectric constant or current leakage of the low k material layer 44 is prevented as well.

Those skilled in the art will readily observe that numerous modifications and alterations of the device may be made while retaining the teachings of the invention. Accordingly, the above disclosure should be construed as limited only by the metes and bound of the appended claims.

What is claimed is:

1. A method of reinforcing a low dielectric constant (low k) material layer against a damage caused by a photoresist stripper, the method comprising:
providing a semiconductor wafer with the a low k material layer atop;
performing a first hydrogen-containing plasma treatment to reinforce a surface of the low k material layer against a corrosion of thecaused by a photoresist stripper;
coating a photoresist layer on the low k material layer;
forming an opening in the photoresist layer to expose a portions of the low k material layer;
performing an ashing process with an oxygen plasma supply to ash the photoresist layer; and
dipping the semiconductor wafer into a photoresist stripper to completely remove the photoresist layer.

2. The method of claim 1 wherein the low k material layer is a silicon oxide based (SiO₂-based) low k material layer.

3. The method of claim 1 whereinthe low k material layer comprises hydrogen silsesquioxane (HSQ), methyl silsesquioxane (MSQ), or hybrid-organic-siloxane-polymer (HOSP).

4. The method of claim 1 wherein a hydrogen plasma is employed in the first hydrogen-containing plasma treatment.

5. The method of claim 4 wherein a radio frequency power (RF power) employed to form the hydrogen plasma ranges from 90 to 150 Watts.

6. The method of claim 4 wherein a flow rate of hydrogen employed to form the hydrogen plasma ranges from 200 to 350 standard cubic centimeters per minute (sccm).

7. The method of claim 4 wherein the hydrogen plasma is formed at a temperature ranging from 200 to 350° C.

8. The method of claim 4 wherein the hydrogen plasma is formed in a pressure ranging from 200 to 350 mTorr.

9. The method of claim 1 wherein the first hydrogen-containing plasma treatment is performed for at least 1 minute.

10. The method of claim 1 wherein the photoresist stripper is ACT-935.

11. The method of claim 1 wherein after performing the ashing process with an oxygen plasma supply to ash the photoresist layer, a second hydrogen-containing plasma treatment is performed to further reinforce the low k material layer against the corrosion of the photoresist stripper before using the photoresist stripper to completely remove the photoresist layer.

12. A method of reinforcing anSiO₂-based low k material layer against a corrosion of caused by a photoresist stripper, the method comprising:
providing a semiconductor wafer with the a low k material layer atop;
coating a photoresist layer on the low k material layer;
forming an opening in the photoresist layer to expose a portions of the low k material layer;
dry etching the low k material layer via through the opening to transfer a pattern in the photoresist layer into the low k material layer;
performing an ashing process with an oxygen plasma supply to ash the photoresist layer;
dipping the semiconductor wafer into a photoresist stripper to completely remove the photoresist layer; and
performing at least one hydrogen-containing plasma treatment to reinforce the low k material layer against the corrosion of caused by the photoresist stripper before dipping the semiconductor wafer into the photoresist stripper.

13. The method of claim 12 wherein the SiO₂-based low k material layer comprises HSQ, MSQ, orHOSP.

14. The method of claim 12 wherein a hydrogen plasma is employed in the first hydrogen-containing plasma treatment.

15. The method of claim 14 wherein an RF power employed to form the hydrogen plasma ranges from 90 to 150 Watts.

16. The method of claim 14 wherein a flow rate of hydrogen employed to form the hydrogen plasma ranges from 200 to 350 sccm.

17. The method of claim 14 wherein the hydrogen plasma is formed at a temperature ranging from 200 to 350° C.

18. The method of claim 14 wherein the hydrogen plasma is formed in a pressure ranging from 200 to 350 mTorr.

19. The method of claim 12 wherein the photoresist stripper is ACT-935.

20. The method of claim 12 wherein the hydrogen-containing plasma treatment is performed before coating the photoresist layer.
